(19) United States
(12) Patent Application Publication
(10) Pub. No.: US 2024/0170456 A1
(43) Pub. Date: May 23, 2024

(54) SEMICONDUCTOR PACKAGE

(71) Applicant: SAMSUNG ELECTRONICS CO., LTD., Suwon-si (KR)

(72) Inventors: Seo Eun KYUNG, Suwon-si (KR); Jun Ho LEE, Suwon-si (KR)

(21) Appl. No.: 18/385,544

(22) Filed: Oct. 31, 2023

(30) Foreign Application Priority Data
Nov. 21, 2022 (KR) 10-2022-0156036

(51) Int. Cl. H01L 25/065; H01L 23/00

(52) U.S. Cl. CPC H01L 25/0657; H01L 24/09; H01L 24/32; H01L 24/33; H01L 24/48; H01L 24/73; H01L 2224/09102; H01L 2224/32145; H01L 2224/32225; H01L 2224/3303; H01L 2224/48149; H01L 2224/48229; H01L 2224/73265; H01L 2225/06506; H01L 2225/0651; H01L 2225/06562; H01L 2924/1431; H01L 2924/1436; H01L 2924/1438

(57) ABSTRACT

A semiconductor package includes a substrate, a substrate pad on an upper surface of the substrate, first and second semiconductor chips stacked on the substrate in a first direction, wherein a sidewall of the first semiconductor chip and a sidewall of the second semiconductor chip are on the same plane, a first chip stack pad on an upper surface of the first semiconductor chip, a second chip stack pad on an upper surface of the second semiconductor chip, a first wire connecting the first chip stack pad with the substrate pad, and a second wire connecting the second chip stack pad with the substrate pad, wherein a first center of an upper surface of the first chip stack pad and a second center of an upper surface of the second chip stack pad are misaligned in the first direction.

### CROSS-REFERENCE TO RELATED APPLICATION

This application claims priority from Korean Patent Application No. 10-2022-0156036, filed on Nov. 21, 2022, in the Korean Intellectual Property Office and all the benefits accruing therefrom under 35 U.S.C. 119, the contents of which in its entirety are herein incorporated by reference.

### BACKGROUND

### 1. Field

The present disclosure relates to a semiconductor package.

### 2. Description of the Related Art

A general stacked package has a structure in which a plurality of substrates are stacked. For example, the stacked package may include semiconductor chips sequentially stacked on a printed circuit board (PCB). Connection pads are formed in the semiconductor chips. The connection pads may be coupled to each other by a bonding wire, so that the semiconductor chips are electrically connected to each other. A logic chip for controlling the semiconductor chips may be packaged on the PCB.

Recently, the demand for portable devices is rapidly increasing in the market of electronic products, and thus, miniaturization and lightweight trend of electronic components packaged in these products are continuously required. In order to realize the miniaturization and lightweight trend of the electronic components, in addition to a technology for reducing individual sizes of the packaged components, a semiconductor package technology for integrating a plurality of individual devices into one package is required. In particular, a semiconductor package for handling a high-frequency signal is required to implement excellent electrical characteristics as well as miniaturization.

### SUMMARY

According to an aspect of the present disclosure, there is provided a semiconductor package, including a substrate, a substrate pad on an upper surface of the substrate, first and second semiconductor chips stacked on the substrate in a first direction, wherein a sidewall of the first semiconductor chip and a sidewall of the second semiconductor chip are on the same plane, a first chip stack pad on an upper surface of the first semiconductor chip, a second chip stack pad on an upper surface of the second semiconductor chip, a first wire connecting the first chip stack pad with the substrate pad, and a second wire connecting the second chip stack pad with the substrate pad, wherein a first center of an upper surface of the first chip stack pad and a second center of an upper surface of the second chip stack pad are misaligned in the first direction.

According to another aspect of the present disclosure, there is provided a semiconductor package, including a substrate, first to third semiconductor chips sequentially stacked on the substrate in a first direction, the second semiconductor chip exposing at least a portion of an upper surface of the first semiconductor chip and the third semiconductor chip for not exposing an upper surface of the second semiconductor chip, a first chip stack pad disposed on the upper surface of the first semiconductor chip and non-overlapped with the second semiconductor chip in the first direction, a second chip stack pad on an upper surface of the second semiconductor chip, a third chip stack pad on an upper surface of the third semiconductor chip, a first wire extended from the second chip stack pad to the first chip stack pad, and a second wire extended from the third chip stack pad to the second chip stack pad, wherein a first center of an upper surface of the second chip stack pad and a second center of an upper surface of the third chip stack pad are spaced apart from each other in a second direction crossing the first direction.

According to yet another aspect of the present disclosure, there is provided a semiconductor package, including a substrate, first to fourth semiconductor chips sequentially stacked on the substrate in a first direction, the second semiconductor chip exposing at least a portion of an upper surface of the first semiconductor chip, the fourth semiconductor chip exposing at least a portion of an upper surface of the third semiconductor chip, and the second and third semiconductor chips having sidewalls placed on the same plane, a plurality of first chip stack pads disposed on the upper surface of the first semiconductor chip, non-overlapped with the second semiconductor chip in the first direction and aligned in a second direction intersecting the first direction, a plurality of second chip stack pads disposed on an upper surface of the second semiconductor chip and aligned in the second direction, a plurality of third chip stack pads on an upper surface of the third semiconductor chip and aligned in the second direction, a first bonding layer provided between the upper surface of the first semiconductor chip and a lower surface of the second semiconductor chip, a second bonding layer provided between the upper surface of the second semiconductor chip and a lower surface of the third semiconductor chip, a first wire extended from each of the second chip stack pads to each of the first chip stack pads, and a second wire extended from each of the third chip stack pads to each of the first chip stack pads, wherein a thickness of the first bonding layer in the first direction is less than that of the second bonding layer in the first direction, each of the plurality of second chip stack pads corresponds to each of the plurality of third chip stack pads, a first center of each of the second chip stack pads and a second center of each of the third chip stack pads are spaced apart from each other in a third direction crossing the first direction and the second direction, and at least a portion of the second chip stack pad overlaps the third chip stack pad in the first direction.

### BRIEF DESCRIPTION OF THE DRAWINGS

Features will become apparent to those of skill in the art by describing in detail exemplary embodiments with reference to the attached drawings, in which:

FIG. 1 is a plan view illustrating a semiconductor package according to some embodiments of the present disclosure.

FIG. 2 is a cross-sectional view taken along line A-A′ of FIG. 1.

FIG. 3 is an enlarged view illustrating a region P of FIG. 2.

FIG. 4 is an exemplary plan view illustrating second and third chip stack pads of FIG. 2.

FIG. 5 is a cross-sectional view illustrating a semiconductor package according to some other embodiments of the present disclosure.

FIG. 6 is an enlarged view illustrating a region Q of FIG. 5.

FIG. 7 is an exemplary plan view illustrating the second and third chip stack pads of FIG. 5.

FIGS. 8 and 9 are exemplary views illustrating a semiconductor package according to some embodiments.

FIG. 10 is a cross-sectional view illustrating a semiconductor package according to some other embodiments of the present disclosure.

FIG. 11 is an enlarged view illustrating a region R of FIG. 10.

FIG. 12 is a plan view illustrating a semiconductor package according to some other embodiments of the present disclosure.

FIG. 13 is a cross-sectional view taken along line B-B′ of FIG. 12.

FIG. 14 is a plan view illustrating a semiconductor package according to some other embodiments of the present disclosure.

FIG. 15 is a cross-sectional view taken along line C-C′ of FIG. 14.

### DETAILED DESCRIPTION

Hereinafter, embodiments according to the technical spirits of the present disclosure will be described with reference to the accompanying drawings.

It will be understood that, although the terms “first”, “second”, “upper portion”, “lower portion”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. Also, a lower element or an upper component could be termed an upper element or an upper component without departing from the technical spirits of the present disclosure.

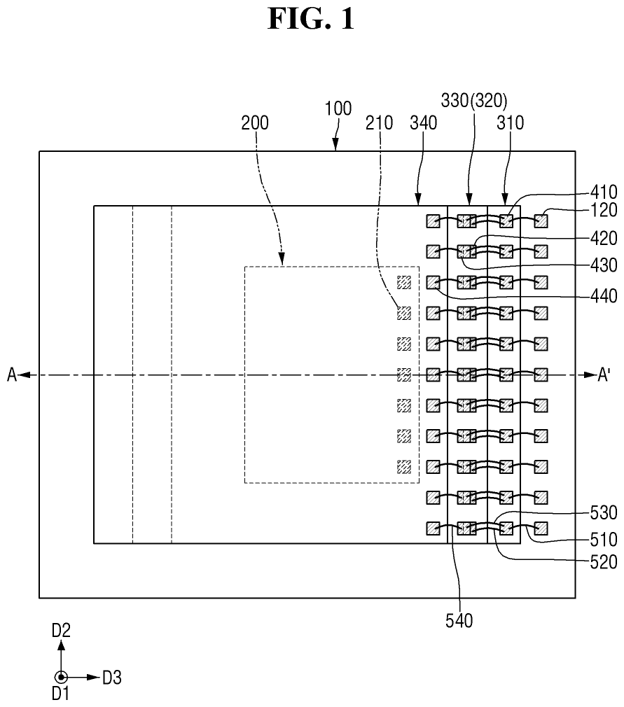

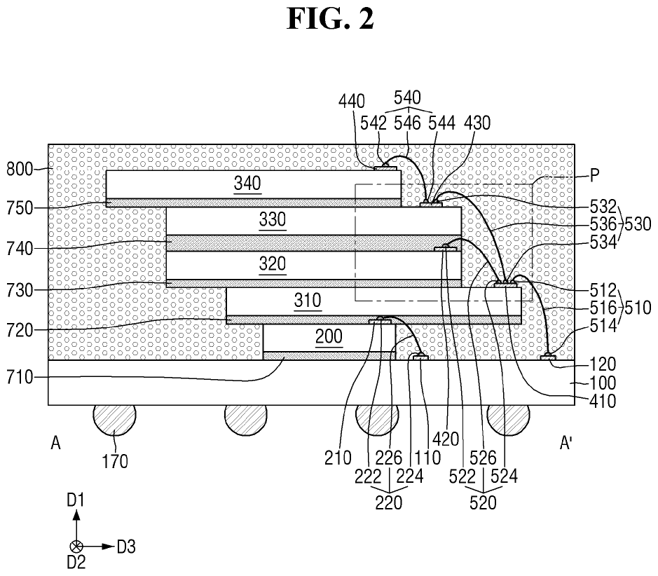

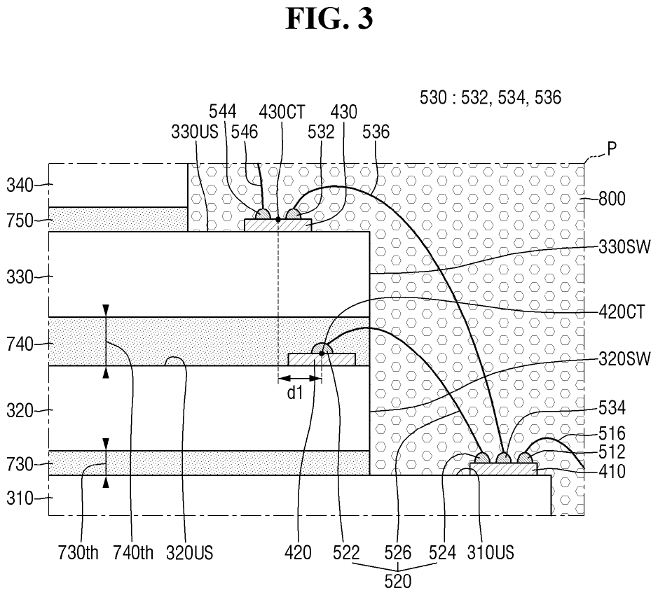

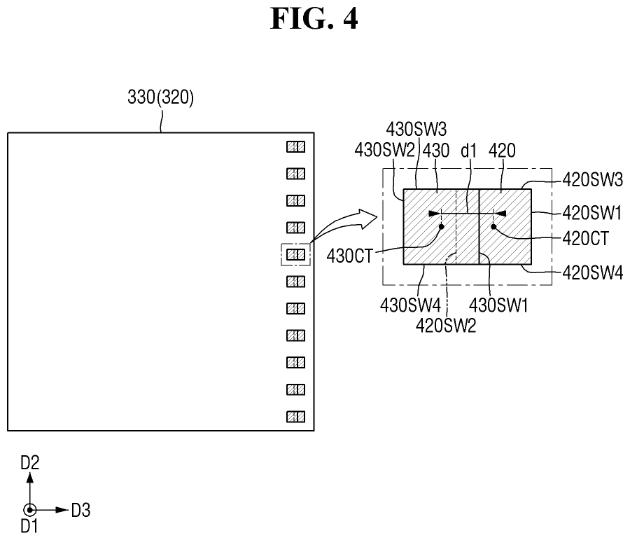

Hereinafter, a semiconductor package according to some embodiments of the present disclosure will be described with reference to FIGS. 1 to 4. FIG. 1 is a plan view illustrating a semiconductor package according to some embodiments of the present disclosure. FIG. 2 is a cross-sectional view taken along line A-A′ of FIG. 1. FIG. 3 is an enlarged view illustrating a region P of FIG. 2. FIG. 4 is an exemplary plan view illustrating second and third chip stack pads of FIG. 2.

Referring to FIGS. 1 to 4, the semiconductor package according to some embodiments of the present disclosure may include a substrate 100, a logic chip 200, first to fourth semiconductor chips 310, 320, 330 and 340 and a molding portion 800.

The substrate 100 may be a printed circuit board (PCB) having a signal pattern provided on an upper surface thereof. The substrate 100 may have a structure in which an insulating layer and a wiring layer are alternately stacked. The signal pattern may include at least one first substrate pad 110 and at least one second substrate pad 120. The at least one first substrate pad 110 and the at least one second substrate pad 120 may be aligned in a second direction D2, respectively. That is, the plurality of first substrate pads 110 may be aligned and spaced apart from each other in the second direction D2. The plurality of second substrate pads 120 may be aligned and spaced apart from each other in the second direction D2. In addition, the at least one first substrate pad 110 and the at least one second substrate pad 120 may be spaced apart from each other in a third direction D3.

In the present disclosure, a first direction D1 may be a thickness direction of the substrate 100 (e.g., extending along a normal direction with respect to the upper surface of the substrate 100), and the second direction D2 and the third direction D3 may be parallel with the upper surface of the substrate 100. The first direction D1, the second direction D2 and the third direction D3 may cross one another, and the first direction D1, the second direction D2, and the third direction D3 may be substantially perpendicular to one another.

The first substrate pads 110 may be pads to which signal wires of the logic chip 200, which will be described later, are connected. The second substrate pad 120 may be pads to which first to fourth wires 510, 520, 530 and 540 of the first to fourth semiconductor chips 310, 320, 330 and 340, which will be described later, are connected.

External terminals 170 may be provided on a lower surface of the substrate 100. Each of the external terminals 170 may include a conductive material. For example, the external terminals 170 may include copper (Cu), aluminum (Al), silver (Ag), tin (Sn), gold (Au), nickel (Ni), lead (Pb), titanium (Ti) or their alloy. For example, as illustrated in FIG. 2, each of the external terminals 170 may have a ball shape. In another example, each of the external terminals 170 may have any suitable shape, e.g., a land, a ball, a pin and/or a pillar. Various modifications may be made in the number, interval, arrangement, shape and the like of the external terminals 170 depending on design. Each of the external terminals 170 may be a solder bump that includes a low melting point metal, e.g., tin (Sn) or a tin (Sn) alloy.

The first to fourth semiconductor chips 310, 320, 330 and 340 may be provided on the substrate 100. The first to fourth semiconductor chips 310, 320, 330 and 340 may be sequentially stacked in the first direction D1. For example, the first semiconductor chip 310 may be disposed at the lowermost position, and the fourth semiconductor chip 340 may be disposed at the uppermost position. The second semiconductor chip 320 may be provided between the first semiconductor chip 310 and the third semiconductor chip 330, and the third semiconductor chip 330 may be provided between the second semiconductor chip 320 and the fourth semiconductor chip 340. Although four semiconductor chips disposed on the logic chip 200 are illustrated in FIG. 2, this is only exemplary for convenience of description, e.g., various modifications may be made in the number of semiconductor chips stacked on the logic chip 200 depending on design.

In some embodiments, the first to fourth semiconductor chips 310, 320, 330 and 340 may be memory chips. For example, the first semiconductor chip 310 may be a flash memory and the second to fourth semiconductor chips 320, 330 and 340 may be dynamic random access memories (DRAMs).

In some embodiments, the first to fourth semiconductor chips 310, 320, 330 and 340 may be disposed in an offset stack structure. For example, the first to fourth semiconductor chips 310, 320, 330 and 340 may be stacked to be inclined, e.g., offset, in the third direction D3. For example, as illustrated in FIG. 2, the first to fourth semiconductor chips 310, 320, 330 and 340 may be stacked to have an ascent inclined stair shape, with the second semiconductor chip 320 and the third semiconductor chip 330 not having an offset stacked structure.

For example, as illustrated in FIG. 3, at least a portion of an upper surface 310US of the first semiconductor chip 310 may be exposed by the offset, e.g., horizontally shifted, second semiconductor chip 320. At least a portion of an upper surface 330US of the third semiconductor chip 330 may be exposed by the offset fourth semiconductor chip 340. However, an upper surface 320US of the second semiconductor chip 320 may not be exposed by the third semiconductor chip 330. At least a portion of the upper surface 3 IOUS of the first semiconductor chip 310 may be covered by the molding portion 800. However, the upper surface 320US of the second semiconductor chip 320 is not covered by the molding portion 800. In addition, a sidewall 320SW of the second semiconductor chip 320 may be placed on the same plane as that of a sidewall 330W of the third semiconductor chip 330, e.g., the sidewalls 320SW and 330SW of the respective second and third semiconductor chips 320 and 330 may be coplanar (e.g., level) with each other.

As illustrated in FIGS. 1 and 2, at least a portion of the first semiconductor chip 310 does not overlap the second semiconductor chip 320 in the first direction D1. At least a portion of the fourth semiconductor chip 340 does not overlap the third semiconductor chip 330 in the first direction D1. However, the second semiconductor chip 320 and the third semiconductor chip 330 may completely overlap each other in the first direction D1.

In some embodiments, the logic chip 200 may be provided on the substrate 100. The logic chip 200 may be provided between the first semiconductor chip 310 and the substrate 100. In a plan view, as illustrated in FIG. 1, a size, e.g., dimensions in the D2 and D3 directions, of the logic chip 200 may be smaller than that of the first semiconductor chip 310. That is, an upper surface of the logic chip 200 may be completely overlapped, e.g., covered in a top view, by the first semiconductor chip 310 in the first direction D1. For example, the logic chip 200 may be a controller for controlling the first to fourth semiconductor chips 310, 320, 330 and 340.

The upper surface of the logic chip 200, e.g., a surface facing the first semiconductor chip 310, may be an active surface thereof. For example, at least one chip pad 210 may be disposed on the upper surface of the logic chip 200. The at least one chip pad 210 may be aligned along one side of the logic chip 200. For example, a plurality of chip pads 210 may be aligned in the second direction D2. The chip pads 210 may be spaced apart from each other in the second direction D2. An interval between the chip pads 210 adjacent to each other may be, e.g., 50 μm to 100 μm. The chip pads 210 may be signal pads connected to an integrated circuit of the logic chip 200 to transfer an electrical signal to the logic chip 200. For example, the chip pads 210 may be disposed in a second bonding layer 720.

The logic chip 200 may be wire-bonded onto the substrate 100 through the signal wires 220. The signal wires 220 may electrically connect the chip pads 210 on the upper surface of the logic chip 200 with the first substrate pads 110 of the substrate 100. The first substrate pads 110 may be disposed to be adjacent to the logic chip 200.

Each of the signal wires 220 may connect one chip pad 210 with one of the first substrate pads 110. Hereinafter, as an example, one of the signal wires 220 will be described. The signal wire 220 may be bonded to the chip pad 210 and the first substrate pad 110 by a stitch bonding method or a ball bonding method.

For example, the signal wire 220 may include a first chip bonding portion 222 bonded to the chip pad 210, a second chip bonding portion 224 bonded to the first substrate pad 110, and a first chip wire loop 226 connecting the first chip bonding portion 222 with the second chip bonding portion 224. The first chip bonding portion 222 and the second chip bonding portion 224 may have a ball shape or a folding shape. A width of each of the first chip bonding portion 222 and the second chip bonding portion 224 may be greater than that of the first chip wire loop 226.

In some embodiments, the first to fourth semiconductor chips 310, 320, 330 and 340 may be wire-bonded onto the substrate 100 through the first to fourth wires 510, 520, 530 and 540, respectively. The first to fourth wires 510, 520, 530 and 540 may electrically connect first to fourth chip stack pads 410, 420, 430 and 440 on the respective upper surfaces of the first to fourth semiconductor chips 310, 320, 330 and 340 with the second substrate pads 120 of the substrate 100. The second substrate pads 120 may be disposed to be adjacent to the first semiconductor chip 310.

In some embodiments, the upper surface 3 IOUS of the first semiconductor chip 310 may be an active surface thereof. For example, at least one or more first chip stack pads 410 may be disposed on the upper surface 310US of the first semiconductor chip 310. Each of the first chip stack pads 410 may be aligned in the second direction D2. An interval between the first chip stack pads 410 adjacent to each other may be, e.g., 50 μm to 100 μm. The first chip stack pads 410 do not overlap the second semiconductor chip 320 in the first direction D1. The first chip stack pads 410 are not disposed in a third bonding layer 730. The first chip stack pads 410 may be covered by the molding portion 800. This is because the first semiconductor chip 310 and the second semiconductor chip 320 have an offset stacked structure.

In some embodiments, the first semiconductor chip 310 may be wire-bonded onto the substrate 100 through the first wires 510. The first wires 510 may electrically connect the second substrate pad 120 with the first chip stack pad 410. Each of the first wires 510 may connect one of the first chip stack pads 410 with one of the second substrate pads 120. Hereinafter, as an example, one of the first wires 510 will be described.

The first wire 510 may be bonded to the first chip stack pad 410 and the second substrate pad 120 by a stitch bonding method or a ball bonding method. For example, the first wire 510 may include a first stack bonding portion 512 bonded to the first chip stack pad 410, a second stack bonding portion 514 bonded to the second substrate pad 120, and a first stack wire loop 516 connecting the first stack bonding portion 512 with the second stack bonding portion 514. The first stack bonding portion 512 and the second stack bonding portion 514 may have a ball shape or a folding shape. A width of each of the first stack bonding portion 512 and the second stack bonding portion 514 may be greater than that of the first stack wire loop 516.

In some embodiments, the upper surface 320US of the second semiconductor chip 320 may be an active surface thereof. For example, at least one or more second chip stack pads 420 may be disposed on the upper surface 320US of the second semiconductor chip 320. Each of the second chip stack pads 420 may be aligned in the second direction D2. An interval between the second chip stack pads 420 adjacent to each other may be, e.g., 50 μm to 100 μm. The second chip stack pads 420 overlap the third semiconductor chip 330 in the first direction D1. The second chip stack pads 420 are disposed in a fourth bonding layer 740. This is because the second semiconductor chip 320 and the third semiconductor chip 330 do not have an offset stacked structure.

In some embodiments, the second semiconductor chip 320 may be wire-bonded onto the substrate 100 through the second wires 520. The second semiconductor chip 320 may be wire-bonded to the first semiconductor chip 310 through the second wires 520. The second wires 520 may electrically connect the first chip stack pad 410 with the second chip stack pad 420 on the first semiconductor chip 310. Each of the second wires 520 may connect one of the second chip stack pads 420 with one of the first chip stack pads 410. Hereinafter, one of the second wires 520 will be described as an example.

The second wire 520 may be bonded to the second chip stack pad 420 and the first chip stack pad 410 by a stitch bonding method or a ball bonding method. For example, the second wire 520 may include a third stack bonding portion 522 bonded to the second chip stack pad 420, a fourth stack bonding portion 524 bonded to the first chip stack pad 410, and a second stack wire loop 526 connecting the third stack bonding portion 522 with the fourth stack bonding portion 524. The third stack bonding portion 522 and the fourth stack bonding portion 524 may have a ball shape or a folding shape. A width of each of the third stack bonding portion 522 and the fourth stack bonding portion 524 may be greater than that of the second stack wire loop 526.

In some embodiments, at least a portion of the second wires 520 may be disposed in the fourth bonding layer 740. This is because that the second semiconductor chip 320 and the third semiconductor chip 330 do not have an offset stacked structure.

In some embodiments, the upper surface 330US of the third semiconductor chip 330 may be an active surface thereof. For example, at least one or more third chip stack pads 430 may be disposed on the upper surface 330US of the third semiconductor chip 330. Each of the third chip stack pads 430 may be aligned in the second direction D2. An interval between the third chip stack pads 430 adjacent to each other may be, e.g., 50 μm to 100 μm. The third chip stack pads 430 do not overlap the fourth semiconductor chip 340 in the first direction D1. The third chip stack pads 430 are not disposed in a fifth bonding layer 750. The third chip stack pads 430 may be covered by the molding portion 800. This is because that the fourth semiconductor chip 340 and the third semiconductor chip 330 have an offset stacked structure.

In some embodiments, the third semiconductor chip 330 may be wire-bonded onto the substrate 100 through the third wires 530. The third semiconductor chip 330 may be wire-bonded to the first semiconductor chip 310 through the third wires 530. The third wires 530 may electrically connect the first chip stack pad 410 with the third chip stack pad 430. Each of the third wires 530 may connect one of the third chip stack pads 430 with one of the first chip stack pads 410. Hereinafter, one of the third wires 530 will be described as an example.

The third wire 530 may be bonded to the third chip stack pad 430 and the first chip stack pad 410 by a stitch bonding method or a ball bonding method. For example, the third wire 530 may include a fifth stack bonding portion 532 bonded to the third chip stack pad 430, a sixth stack bonding portion 534 bonded to the first chip stack pad 410, and a third stack wire loop 536 connecting the fifth stack bonding portion 532 with the sixth stack bonding portion 534. The fifth stack bonding portion 532 and the sixth stack bonding portion 534 may have a ball shape or a folding shape. A width of each of the fifth stack bonding portion 532 and the sixth stack bonding portion 534 may be greater than that of the third stack wire loop 536.

In some embodiments, an upper surface of the fourth semiconductor chip 340 may be an active surface thereof. For example, at least one or more fourth chip stack pads 440 may be disposed on the fourth semiconductor chip 340. Each of the fourth chip stack pads 440 may be aligned in the second direction D2. An interval between the fourth chip stack pads 440 adjacent to each other may be, e.g., 50 μm to 100 μm.

In some embodiments, the fourth semiconductor chip 340 may be wire-bonded onto the substrate 100 through the fourth wires 540. The fourth semiconductor chip 340 may be wire-bonded to the third semiconductor chip 330 through the fourth wires 540. The fourth wires 540 may electrically connect the third chip stack pad 430 with the fourth chip stack pad 440. Each of the fourth wires 540 may connect one of the fourth chip stack pad 440 with one of the third chip stack pad 430. Hereinafter, one of the fourth wires 540 will be described as an example.

The fourth wire 540 may be bonded to the fourth chip stack pad 440 and the third chip stack pad 430 by a stitch bonding method or a ball bonding method. For example, the fourth wire 540 may include a seventh stack bonding portion 542 bonded to the fourth chip stack pad 440, an eighth stack bonding portion 544 bonded to the third chip stack pad 430, and a fourth stack wire loop 546 connecting the seventh stack bonding portion 542 with the eighth stack bonding portion 544. The seventh stack bonding portion 542 and the eighth stack bonding portion 544 may have a ball shape or a folding shape. A width of each of the seventh stack bonding portion 542 and the eighth stack bonding portion 544 may be greater than that of the fourth stack wire loop 546.

In some embodiments, the first bonding layer 710 may be provided between the logic chip 200 and the substrate 100. For example, the first bonding layer 710 may be disposed on a lower surface of the logic chip 200. The logic chip 200 and the substrate 100 may be bonded to each other through the first bonding layer 710.

In some embodiments, the second bonding layer 720 may be provided between the first semiconductor chip 310 and the logic chip 200. For example, the second bonding layer 720 may be disposed on a lower surface of the first semiconductor chip 310. The first semiconductor chip 310 and the logic chip 200 may be bonded to each other through the second bonding layer 720.

In some embodiments, the third bonding layer 730 may be provided between the second semiconductor chip 320 and the first semiconductor chip 310. For example, the third bonding layer 730 may be disposed on a lower surface of the second semiconductor chip 320. The second semiconductor chip 320 and the first semiconductor chip 310 may be bonded to each other through the third bonding layer 730.

In some embodiments, the fourth bonding layer 740 may be provided between the third semiconductor chip 330 and the second semiconductor chip 320. For example, the fourth bonding layer 740 may be disposed on a lower surface of the third semiconductor chip 330. The third semiconductor chip 330 and the second semiconductor chip 320 may be bonded to each other through the fourth bonding layer 740.

In some embodiments, the fifth bonding layer 750 may be provided between the fourth semiconductor chip 340 and the third semiconductor chip 330. For example, the fifth bonding layer 750 may be disposed on a lower surface of the fourth semiconductor chip 340. The fourth semiconductor chip 340 and the third semiconductor chip 330 may be bonded to each other through the fifth bonding layer 750.

In some embodiments, at least a portion of the second bonding layer 720 does not overlap the second semiconductor chip 320 in the first direction D1. At least a portion of the third bonding layer 730 does not overlap the first semiconductor chip 310 in the first direction D1. On the other hand, the third bonding layer 730 completely overlaps the third semiconductor chip 330 in the first direction D1. The fourth bonding layer 740 completely overlaps the second semiconductor chip 320 in the first direction D1 but does not overlap at least a portion of the fourth semiconductor chip 340 in the first direction D1. This is because that the fourth semiconductor chip 340 and the third semiconductor chip 330 have an offset stacked structure, the third semiconductor chip 330 and the second semiconductor chip 320 do not have an offset stacked structure, and the second semiconductor chip 320 and the first semiconductor chip 310 have an offset stacked structure.

Each of the first to fifth bonding layers 710, 720, 730, 740 and 750 may include, e.g., a non-conductive film (NCF), a non-conductive paste (NCP), an insulating polymer or an epoxy resin.

In FIGS. 3 and 4, the second chip stack pad 420 and the third chip stack pad 430 may not be aligned with each other. That is, the second chip stack pad 420 and the third chip stack pad 430 may be misaligned. The expression “A and B are misaligned” means that the center of A and the center of B are not aligned in a vertical direction (i.e., along the first direction D1). That is, the expression “A and B are misaligned” means that the center of A and the center of B are spaced apart from each other in a horizontal direction. “The center of A” is the center of gravity of A in a top view. In addition, the term “the center of A” means a crossing point of a middle line between sides of A, which are spaced apart from each other in the third direction D3, and a middle line between sides of A, which are spaced apart from each other the second direction D2, in the top view (i.e., in a plan view). For example, referring to FIG. 3, a first center 420CT of the second chip stack pad 420 and a second center 430CT of the third chip stack pad 430 may be misaligned in the first direction D1.

In detail, referring to FIG. 4, the second chip stack pad 420 includes a first sidewall 420SW1 and a second sidewall 420SW2, which are spaced apart from each other in the third direction D3. The second chip stack pad 420 includes a third sidewall 420SW3 and a fourth sidewall 420SW4, which are spaced apart from each other in the second direction D2. The first center 420CT may be a crossing point of a middle line between the first sidewall 420SW1 of the second chip stack pad 420 and the second sidewall 420SW2 of the second chip stack pad 420, and a middle line between the third sidewall 420SW3 of the second chip stack pad 420 and the fourth sidewall 420SW4 of the second chip stack pad 420.

The third chip stack pad 430 includes a first sidewall 430SW1 and a second sidewall 430SW2, which are spaced apart from each other in the third direction D3. The third chip stack pad 430 includes a third sidewall 430SW3 and a fourth sidewall 430SW4, which are spaced apart from each other in the second direction D2. The second center 430CT may be a crossing point of a middle line between the first sidewall 430SW1 of the third chip stack pad 430 and the second sidewall 430SW2 of the third chip stack pad 430, and a middle line between the third sidewall 430SW3 of the third chip stack pad 430 and the fourth sidewall 430SW4 of the third chip stack pad 430.

In some embodiments, the second sidewall 420SW2 of the second chip stack pad 420 may face the first sidewall 430SW1 of the third chip stack pad 430, e.g., as viewed in a top view (dashed line indicating the second sidewall 420SW2 of the second chip stack pad 420 and the solid line to its right indicating the first sidewall 430SW1 of the third chip stack pad 430 in the enlarged portion of FIG. 4). This is because at least a portion of the second chip stack pad 420 overlaps the third chip stack pad 430 in the first direction D1, e.g., the third chip stack pad 430 overlaps (e.g., covers) a portion of an upper surface of the second chip stack pad 420.

In some embodiments, the first center 420CT and the second center 430CT may be spaced apart from each other in the third direction D3. That is, the second chip stack pad 420 and the third chip stack pad 430 may be spaced apart from each other in the third direction D3. A first spaced distance d1 between the first center 420CT and the second center 430CT in the third direction D3 may be 10 μm or more.

According to some embodiments of the present disclosure, the first center 420CT and the second center 430CT are misaligned. Therefore, even if the substrate 100 were to be deformed by an external temperature, damage applied to the third chip stack pad 430 and the second chip stack pad 420 may be reduced. As a result, a semiconductor package with improved reliability may be manufactured.

For example, as illustrated in FIG. 3, at least a portion of the third chip stack pad 430 may overlap the second chip stack pad 420 in the first direction D1. In this case, the second center 430CT may not overlap the second chip stack pad 420 in the first direction D1. In another example, at least a portion of the third chip stack pad 430 may overlap the second chip stack pad 420 in the first direction D1, while the second center 430CT may overlap the second chip stack pad 420 in the first direction D1.

In some embodiments, a thickness 730th of the third bonding layer 730 in the first direction D1 is smaller than a thickness 740th in the fourth bonding layer 740 in the first direction D1.

The second semiconductor chip 320 and the third semiconductor chip 330 do not have an offset stacked structure, e.g., the second semiconductor chip 320 and the third semiconductor chip 330 may completely overlap each other in the first direction D1 with all their lateral sidewalls being coplanar with each other. Therefore, the second chip stack pad 420 on the upper surface 320US of the second semiconductor chip 320 is disposed in the fourth bonding layer 740, e.g., the fourth bonding layer 740 may completely cover the second chip stack pad 420 on the upper surface 320US. Further, at least a portion of the second wire 520 is disposed in the fourth bonding layer 740. On the other hand, the first semiconductor chip 310 and the second semiconductor chip 320 have an offset stacked structure. Therefore, the first chip stack pad 410 on the upper surface 3 IOUS of the first semiconductor chip 310 may not be disposed in the third bonding layer 730. The first wire 510 may not be disposed in the third bonding layer 730.

For example, as illustrated in FIG. 3, the thickness 740th of the fourth bonding layer 740 in the first direction D1 may be greater than the thickness of the second chip stack pad 420 in the first direction. In another example, the thickness 730th of the third bonding layer 730 in the first direction D1 may be smaller than the thickness 740th of the fourth bonding layer 740 in the first direction D1.

Referring back to FIG. 2, the molding portion 800 may cover the upper surface of the substrate 100 and the first to fourth semiconductor chips 310, 320, 330 and 340. The molding portion 800 may fill a space between the first semiconductor chip 310 and the logic chip 200 and cover the sidewalls and the upper surfaces of the first to fourth semiconductor chips 310, 320, 330 and 340. The molding portion 800 may cover the first substrate pad 110, the second substrate pad 120, the first chip stack pad 410, the third chip stack pad 430, and the fourth chip stack pad 440. However, the molding portion 800 does not cover the second chip stack pad 420, e.g., the molding portion 800 may not be in direct contact with the second chip stack pad 420. The molding portion 800 may include an insulating polymer material, e.g., an epoxy molding compound (EMC).

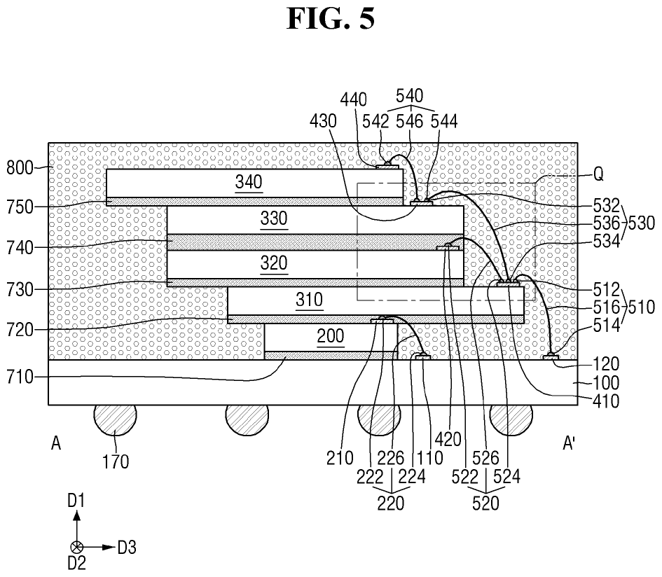

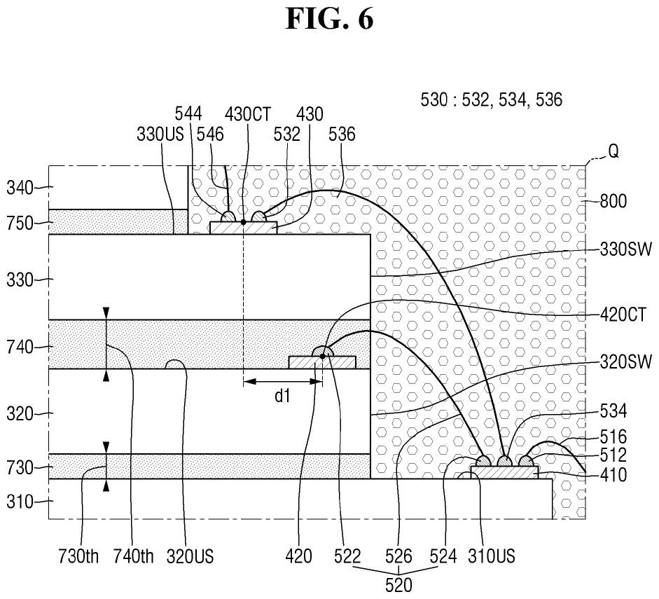

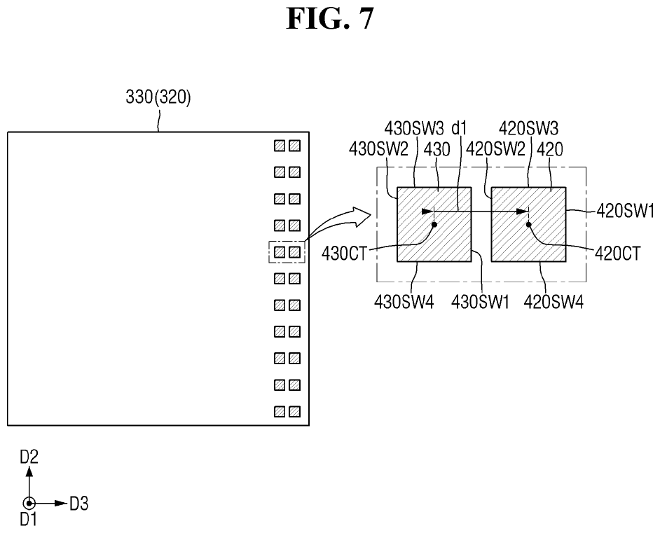

Hereinafter, a semiconductor package according to some other embodiments of the present disclosure will be described with reference to FIGS. 5 to 7. For convenience of description, the following description will be based on differences from those described with reference to FIGS. 1 to 4. FIG. 5 is a cross-sectional view illustrating a semiconductor package according to some other embodiments of the present disclosure. FIG. 6 is an enlarged view illustrating a region Q of FIG. 5. FIG. 7 is an exemplary plan view illustrating the second and third chip stack pads of FIG. 5.

Referring to FIGS. 5 to 7, the second chip stack pad 420 and the third chip stack pad 430 may not overlap each other in the first direction D1, e.g., the second chip stack pad 420 and the third chip stack pad 430 may have a non-overlapping relationship in the first direction D1. The second chip stack pad 420 and the third chip stack pad 430 may be spaced apart from each other in the third direction D3. The first center 420CT and the second center 430CT may be misaligned in the first direction D1. The first center 420CT and the second center 430CT may be spaced apart from each other in the third direction D3, e.g., a distance between the first center 420CT and the second center 430CT in the third direction D3 may be larger than a width of each of the second chip stack pad 420 and the third chip stack pad 430 in the third direction D3 (e.g., due to horizontal spacing between facing sidewalls).

In some embodiments, the second sidewall 420SW2 of the second chip stack pad 420 may face the first sidewall 430SW1 of the third chip stack pad 430. The second sidewall 420SW2 of the second chip stack pad 420 and the first sidewall 430SW1 of the third chip stack pad 430 may be spaced apart from each other in the third direction D3. The second center 430CT may not overlap the second chip stack pad 420 in the first direction D1. This is because that the second chip stack pad 420 and the third chip stack pad 430 do not completely overlap each other in the first direction D1.

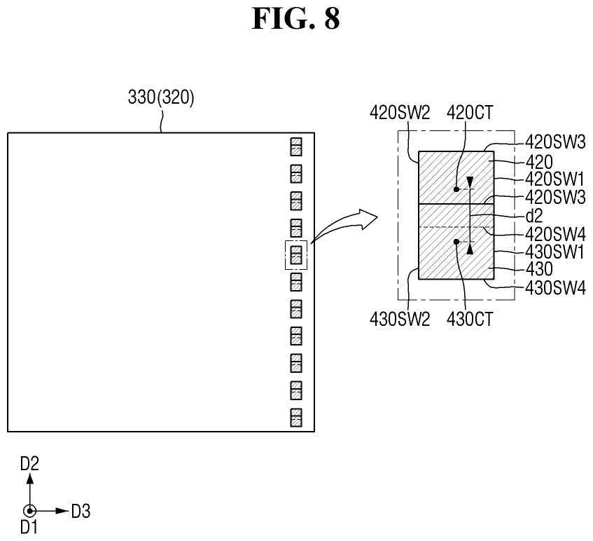

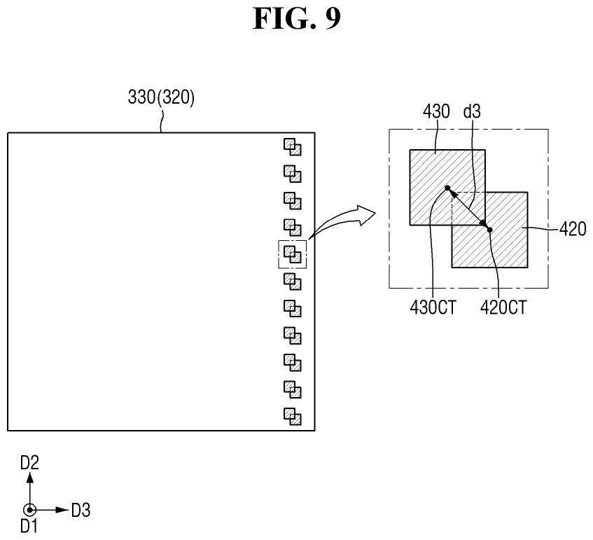

Hereinafter, a semiconductor package according to some other embodiments of the present disclosure will be described with reference to FIGS. 8 and 9. For convenience of description, the following description will be based on differences from those described with reference to FIGS. 1 to 4. FIGS. 8 and 9 are exemplary views illustrating a semiconductor package according to some embodiments.

First, referring to FIG. 8, the first center 420CT of the second chip stack pad 420 may be spaced apart from the second center 430CT of the third chip stack pad 430 in the second direction D2. The first center 420CT of the second chip stack pad 420 is not spaced apart from the second center 430CT of the third chip stack pad 430 in the third direction D3. Even in this case, at least a portion of the second chip stack pad 420 overlaps the third chip stack pad 430 in the first direction D1. A second spaced distance d2 between the first center 420CT and the second center 430CT in the second direction D2 may be 10 μm or more.

In some embodiments, the first sidewall 420SW1 of the second chip stack pad 420 and the first sidewall 430SW1 of the third chip stack pad 430 may be placed on the same plane, e.g., may be coplanar with each other. The second sidewall 420SW2 of the second chip stack pad 420 and the second sidewall 430SW2 of the third chip stack pad 430 may be placed on the same plane, e.g., may be coplanar with each other. The fourth sidewall 420SW4 of the second chip stack pad 420 may face the third sidewall 430SW3 of the third chip stack pad 430.

Referring to FIG. 9, the first center 420CT of the second chip stack pad 420 may be spaced apart from the second center 430CT of the third chip stack pad 430 in the second direction D2 and the third direction D3. That is, the first center 420CT may be spaced apart from the second center 430CT in a random direction between the second direction D2 and the third direction D3, e.g., the first center 420CT may be spaced apart from the second center 430CT in a diagonal direction relative to the second and third directions D2 and D3. Even in this case, at least a portion of the second chip stack pad 420 overlaps the third chip stack pad 430 in the first direction D1. A third spaced distance d3 between the first center 420CT and the second center 430CT may be 10 μm or more.

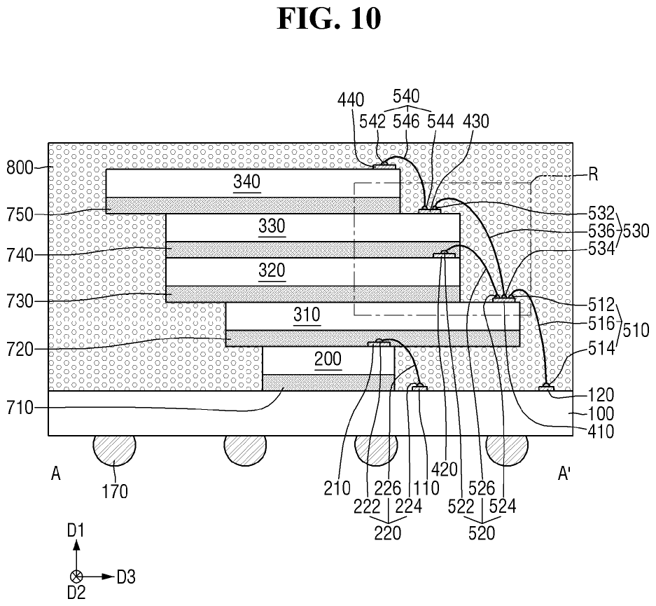

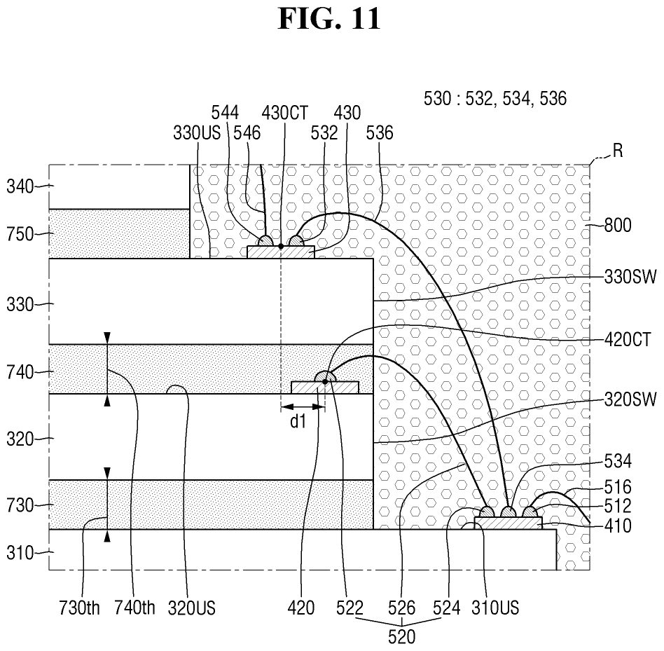

Hereinafter, a semiconductor package according to some other embodiments of the present disclosure will be described with reference to FIGS. 10 and 11. For convenience of description, the following description will be based on differences from those described with reference to FIGS. 1 to 4. FIG. 10 is a cross-sectional view illustrating a semiconductor package according to some other embodiments of the present disclosure. FIG. 11 is an enlarged view illustrating a region R of FIG. 10.

Referring to FIGS. 10 and 11, in the semiconductor package according to some embodiments, thicknesses of the first to fifth bonding layers 710, 720, 730, 740 and 750 in the first direction D1 may be all the same.

For example, as illustrated in FIG. 11, the thickness 730th of the third bonding layer 730 in the first direction D1 and the thickness 740th of the fourth bonding layer 740 in the first direction D1 may be the same as each other. The thickness 730th of the third bonding layer 730 in the first direction D1 is greater than the thickness of the first chip stack pad 410 in the first direction D1. Therefore, the first chip stack pad 410 may be completely overlapped by the third bonding layer 730 in the third direction D3, e.g., the third bonding layer 730 may extend above the first chip stack pad 410 in the first direction D1. Likewise, the thickness of the fifth bonding layer 750 in the first direction D1 may be the same as the thickness 740th of the fourth bonding layer 740 in the first direction D1.

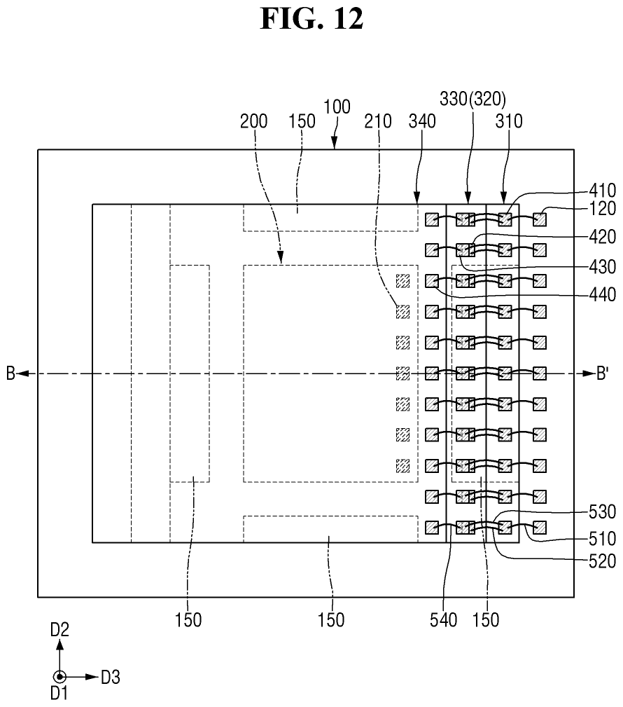

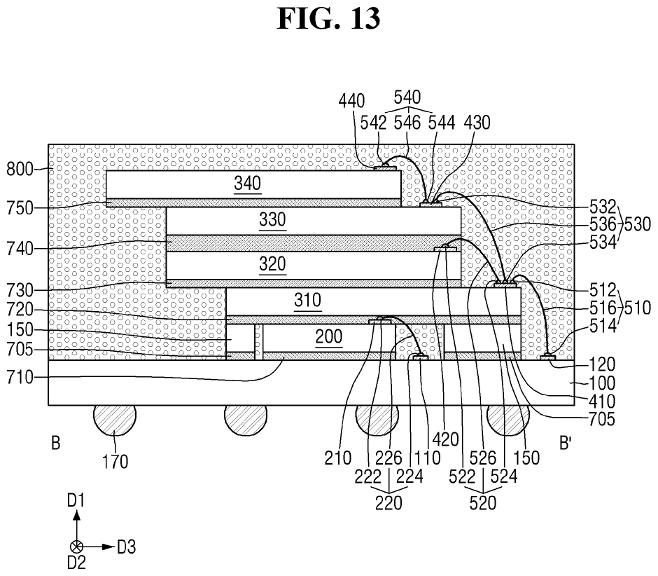

Hereinafter, a semiconductor package according to some other embodiments of the present disclosure will be described with reference to FIGS. 12 and 13. For convenience of description, the following description will be based on differences from those described with reference to FIGS. 1 to 4. FIG. 12 is a plan view illustrating a semiconductor package according to some other embodiments of the present disclosure. FIG. 13 is a cross-sectional view taken along line B-B′ of FIG. 12.

Referring to FIGS. 12 and 13, the semiconductor package according to some embodiments may further include at least one spacer 150 on the substrate 100.

The spacer 150 may be disposed between the substrate 100 and the first semiconductor chip 310. For example, the spacer 150 may be spaced apart from the logic chip 200 in the second direction D2 or the third direction D3. When the logic chip 200 has a rectangular shape in a plan view, at least one or more spacers 150 may be respectively disposed on sides of the logic chip 200.

At least one or more spacers 150 may support the first to fourth semiconductor chips 310, 320, 330 and 340 on the substrate 100. The spacers 150 may be bonded to the substrate 100 by using sub-bonding layers 705. For example, the sub-bonding layers 705 may be provided on lower surfaces of the spacers 150. The sub-bonding layer 705 may include, e.g., a non-conductive film (NCF), a non-conductive paste (NCP), an insulating polymer or an epoxy resin.

In some embodiments, load of the first to fourth semiconductor chips 310, 320, 330 and 340 may be uniformly distributed using the spacers 150. Therefore, the first to fourth semiconductor chips 310, 320, 330 and 340 may be supported in a balanced manner. In addition, as the spacers 150 are disposed to surround the logic chip 200, the load of the first to fourth semiconductor chips 310, 320, 330 and 340 may be prevented from being concentrated on the logic chip 200. Further, the logic chip 200 may be protected from an external impact. Although four semiconductor chips are stacked on the logic chip 200 in FIG. 13, any suitable number of semiconductor chips may be used.

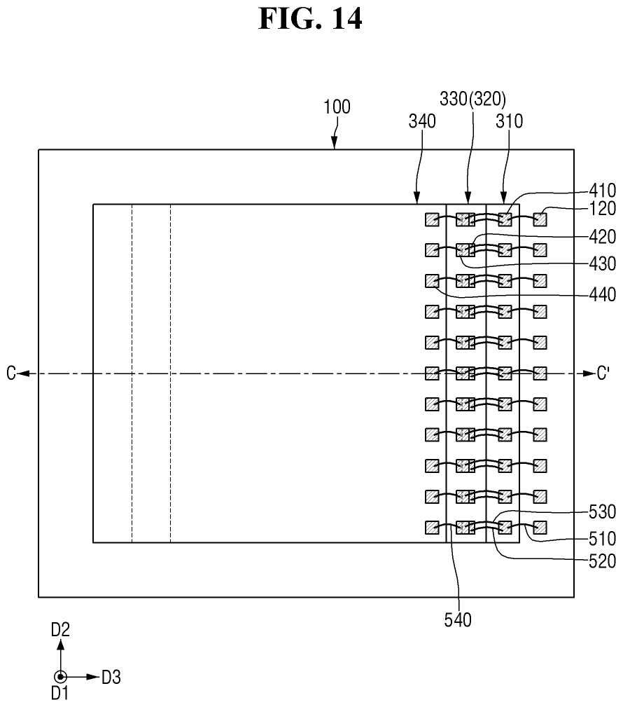

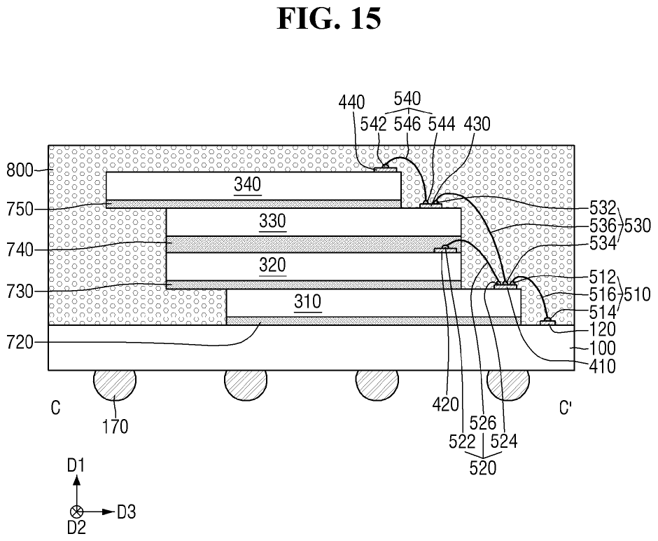

Hereinafter, a semiconductor package according to some other embodiments of the present disclosure will be described with reference to FIGS. 14 and 15. For convenience of description, the following description will be based on differences from those described with reference to FIGS. 1 to 4. FIG. 14 is a plan view illustrating a semiconductor package according to some other embodiments of the present disclosure. FIG. 15 is a cross-sectional view taken along line C-C′ of FIG. 14.

Referring to FIGS. 14 and 15, the semiconductor package according to some embodiments may not include the logic chip. In addition, the semiconductor package according to some embodiments may not include the first bonding layer 710. Further, the semiconductor package according to some embodiments may not include the first substrate pad 110.

The second bonding layer 720 may be provided between the first semiconductor chip 310 and the substrate 100. The first semiconductor chip 310 and the substrate 100 may be bonded to each other using the second bonding layer 720. In some embodiments, the first semiconductor chip 310 may be a logic chip, e.g., a controller. In another embodiment, the first semiconductor chip 310 may be a memory chip.

By way of summation and review, embodiments provide a semiconductor package with improved reliability. That is, according to embodiments, the position of upper and lower pads of overlapping semiconductor chips in a same-die stack structure is shifted by shifting the alignment of the semiconductor chips. Accordingly, even if bending of the stack structure of the semiconductor chips occurs in a cooling environment, damage applied to the upper pad can be reduced by reducing the repulsive force by the lower pad.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a substrate;
a substrate pad on an upper surface of the substrate;
a first semiconductor chip and a second semiconductor chip stacked on the substrate in a first direction, a sidewall of the first semiconductor chip and a sidewall of the second semiconductor chip being coplanar;
a first chip stack pad on an upper surface of the first semiconductor chip;
a second chip stack pad on an upper surface of the second semiconductor chip, a first center of an upper surface of the first chip stack pad and a second center of an upper surface of the second chip stack pad being misaligned in the first direction;
a first wire connecting the first chip stack pad with the substrate pad; and
a second wire connecting the second chip stack pad with the substrate pad.

2. The semiconductor package as claimed in claim 1, wherein the first center is spaced apart from the second center in a second direction intersecting the first direction.

3. The semiconductor package as claimed in claim 1, wherein the first center is spaced apart from the second center in a second direction and a third direction, the first direction, the second direction, and the third direction intersecting one another.

4. The semiconductor package as claimed in claim 1, wherein at least a portion of the first chip stack pad overlaps the second chip stack pad in the first direction.

5. The semiconductor package as claimed in claim 1, wherein the first chip stack pad does not completely overlap the second chip stack pad in the first direction.

6. The semiconductor package as claimed in claim 1, wherein a spaced distance between the first center and the second center is 10 μm or more.

7. The semiconductor package as claimed in claim 1, further comprising a bonding layer between the first semiconductor chip and the second semiconductor chip, the bonding layer bonding the first semiconductor chip to the second semiconductor chip.

8. The semiconductor package as claimed in claim 7, wherein the bonding layer covers the first chip stack pad.

9. A semiconductor package, comprising:
a substrate;
a first semiconductor chip, a second semiconductor chip, and a third semiconductor chip sequentially stacked on the substrate in a first direction, the second semiconductor chip exposing at least a portion of an upper surface of the first semiconductor chip, and the third semiconductor chip not exposing an upper surface of the second semiconductor chip;
a first chip stack pad on the upper surface of the first semiconductor chip, the first chip stack pad and the second semiconductor chip having a non-overlapping relationship in the first direction;
a second chip stack pad on the upper surface of the second semiconductor chip;
a third chip stack pad on an upper surface of the third semiconductor chip, a first center of an upper surface of the second chip stack pad and a second center of an upper surface of the third chip stack pad being spaced apart from each other in a second direction crossing the first direction;
a first wire extended from the second chip stack pad to the first chip stack pad; and
a second wire extended from the third chip stack pad to the second chip stack pad.

10. The semiconductor package as claimed in claim 9, further comprising:
a first bonding layer between the upper surface of the first semiconductor chip and a lower surface of the second semiconductor chip; and
a second bonding layer between the upper surface of the second semiconductor chip and a lower surface of the third semiconductor chip, a thickness of the first bonding layer in the first direction being less than a thickness of the second bonding layer in the first direction.

11. The semiconductor package as claimed in claim 10, wherein at least a portion of the first wire is in the second bonding layer.

12. The semiconductor package as claimed in claim 9, wherein the first center and the second center are spaced apart from each other in a third direction intersecting the second direction.

13. The semiconductor package as claimed in claim 9, wherein a spaced distance between the first center and the second center is 10 μm or more.

14. The semiconductor package as claimed in claim 9, wherein at least a portion of the second chip stack pad overlaps the third chip stack pad in the first direction.

15. The semiconductor package as claimed in claim 9, wherein the second chip stack pad does not completely overlap the third chip stack pad in the first direction.

16. A semiconductor package, comprising:
a substrate;
a first semiconductor chip, a second semiconductor chip, a third semiconductor chip, and a fourth semiconductor chip sequentially stacked on the substrate in a first direction, the second semiconductor chip exposing at least a portion of an upper surface of the first semiconductor chip, the fourth semiconductor chip exposing at least a portion of an upper surface of the third semiconductor chip, and the second and third semiconductor chips having sidewalls that are coplanar with each other;
a plurality of first chip stack pads on the upper surface of the first semiconductor chip, the plurality of first chip stack pads having a non-overlapping relationship with the second semiconductor chip in the first direction and being aligned in a second direction intersecting the first direction;
a plurality of second chip stack pads on an upper surface of the second semiconductor chip and aligned in the second direction;
a plurality of third chip stack pads on the upper surface of the third semiconductor chip and aligned in the second direction, each of the plurality of third chip stack pads corresponding to each of the plurality of second chip stack pads;
a first bonding layer between the upper surface of the first semiconductor chip and a lower surface of the second semiconductor chip;
a second bonding layer between the upper surface of the second semiconductor chip and a lower surface of the third semiconductor chip, a thickness of the first bonding layer in the first direction being less than a thickness of the second bonding layer in the first direction;
a first wire extended from each of the second chip stack pads to each of the first chip stack pads; and
a second wire extended from each of the third chip stack pads to each of the first chip stack pads,
wherein a first center of each of the plurality of second chip stack pads and a second center of each of the plurality of third chip stack pads are spaced apart from each other in a third direction crossing the first direction and the second direction, at least a portion of each of the plurality of second chip stack pads overlapping a corresponding one of the plurality of third chip stack pads in the first direction.

17. The semiconductor package as claimed in claim 16, wherein the first center and the second center are spaced apart from each other in the second direction.

18. The semiconductor package as claimed in claim 16, wherein at least a portion of the first wire overlaps the second semiconductor chip in the third direction.

19. The semiconductor package as claimed in claim 16, wherein each of the plurality of second chip stack pads and the plurality of third chip stack pads overlaps the fourth semiconductor chip in the first direction.

20. The semiconductor package as claimed in claim 16, wherein a spaced distance between the first center and the second center is 10 μm or more.
